(19) United States
(12) Patent Application Publication
(10) Pub. No.: US 2025/0212617 A1
(43) Pub. Date: Jun. 26, 2025

(54) DISPLAY DEVICE

(71) Applicant: LG DISPLAY CO., LTD., Seoul (KR)

(72) Inventors: Joohwan HWANG, Paju-si (KR); Youngjune GO, Paju-si (KR); SungHo LEE, Paju-si (KR)

(73) Assignee: LG DISPLAY CO., LTD., Seoul (KR)

(21) Appl. No.: 18/925,349

(22) Filed: Oct. 24, 2024

(30) Foreign Application Priority Data
Dec. 22, 2023 (KR) 10-2023-0190380

(51) Int. Cl. H10K 59/122; H10K 59/80

(52) U.S. Cl. CPC H10K 59/122; H10K 59/8731

(57) ABSTRACT

A display device includes a substrate including a display area capable of displaying an image and a non-display area different from the display area, a plurality of light emitting devices disposed on the substrate, a bank for defining an emission area of each of the plurality of light emitting devices, a first inorganic layer on the plurality of light emitting devices and the bank, a first organic layer on the first inorganic layer, a second inorganic layer on the first organic layer, and a stopper disposed outside the display area and located on the outermost upper part of the bank, wherein at least a portion of the stopper may be disposed further outside the first organic layer, and an inner side of the stopper may have a reverse taper shape.

### CROSS-REFERENCE TO RELATED APPLICATION

This application claims the priority of Korean Patent Application No. 10-2023-0190380, filed on Dec. 22, 2023, which is hereby incorporated by reference in its entirety.

### BACKGROUND

### Field of the Disclosure

The present disclosure relates to a display device.

### Description of the Background

A display panel of a display device may include a display area where an image is displayed and a non-display area where the image is not displayed. There may be disposed various structures, circuits, and lines in the non-display area (also referred to as “bezel”) of the display panel. Accordingly, there may not be easy to reduce the bezel of the display panel.

### SUMMARY

Accordingly, the present disclosure is directed to a display device that substantially obviates one or more of problems due to limitations and disadvantages described above.

More specifically, the present disclosure is to provide a display device having an extremely narrow bezel structure.

The present disclosure is also to provide a display device with an organic layer overflow prevention structure which enables an extremely narrow bezels.

Further, the present disclosure is to provide a display device with the high reliability while enabling an extremely narrow bezel.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device includes a substrate including a display area capable of displaying an image and a non-display area different from the display area, a plurality of light emitting devices disposed on the substrate, a bank for defining an emission area of each of the plurality of light emitting devices, a first inorganic layer on the plurality of light emitting devices and the bank, a first organic layer on the first inorganic layer, a second inorganic layer on the first organic layer, and a stopper disposed outside the display area and located on the outermost upper part of the bank.

At least a portion of the stopper may be disposed further outside the first organic layer.

An inner side of the stopper may have a reverse taper shape.

An outer side of the stopper may have a regular taper shape.

The display device according to aspects of the present disclosure may further include a separation material layer disposed on the stopper, including the same material as a common intermediate layer, and separated from the common intermediate layer.

The separation material layer may not be disposed on the outer side of the stopper.

The display device according to aspects of the present disclosure may further include a metal patterning layer disposed on the separation material layer.

The metal patterning layer may not be disposed on the outer side of the stopper.

The display device according to aspects of the present disclosure may further include a capping layer disposed on a common electrode.

The capping layer may not be disposed on the outer side of the stopper.

The first inorganic layer may extend along the inner side of the stopper to an upper portion of the stopper, and may be disposed on the separation material layer.

The first inorganic layer may not be disposed on the outer side of the stopper.

The first organic layer may extend to an upper portion of the stopper, and may not be disposed on the outer side of the stopper.

The second inorganic layer may extend from the display area to the non-display area, and the second inorganic layer may extend along the outer side of the stopper and the outer side of the bank.

In another aspect of the present disclosure, a display device includes a substrate including a display area and a non-display area, a plurality of light emitting devices disposed on the substrate, a first organic layer disposed on the plurality of light emitting devices, and a stopper disposed further outward than the outermost light emitting device among the plurality of light-emitting devices, located outside the first organic layer, and having an inner side with a reverse taper shape.

The display device according to aspects of the present disclosure may further include an intermediate layer constituting the plurality of light emitting devices, present on the inner side of the stopper, and not present on an outer side of the stopper, and a separation material layer disposed on an upper portion of the stopper, separated from the intermediate layer, and including the same material as the intermediate layer.

An outer side of the stopper may have a regular taper shape.

Various aspects of the present disclosure may provide a display device with an extremely narrow bezel structure through a stopper structure.

Various aspects of the present disclosure may provide a display device having an organic layer overflow prevention structure that enables an extremely narrow bezel through a stopper structure.

Various aspects of the present disclosure may provide a display device having a stopper structure with high reliability while enabling an extremely narrow bezel.

According to aspects of the present disclosure, it is possible to reduce the weight of the display device by having an extremely narrow bezel structure.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a system configuration diagram of a display device according to aspects of the present disclosure;

FIG. 2 illustrates a display panel according to aspects of the present disclosure;

FIG. 3 illustrates a substrate of a display panel according to aspects of the present disclosure;

FIG. 4 is a cross-sectional view of a display panel according to aspects of the present disclosure;

FIG. 5 is a cross-sectional view of a display panel according to aspects of the present disclosure.

FIGS. 6 to 11 illustrate a manufacturing process of a display panel according to aspects of the present disclosure;

FIG. 12 illustrates a substrate of a display panel according to aspects of the present disclosure;

FIG. 13 is a cross-sectional view of second to fourth non-display areas of a display panel according to aspects of the present disclosure;

FIG. 14 is a cross-sectional view of a first non-display area of a display panel according to aspects of the present disclosure;

FIG. 15 is another cross-sectional view of second to fourth non-display areas of the display panel according to aspects of the present disclosure and

FIG. 16 is another cross-sectional view of the first non-display area of the display panel according to aspects of the present disclosure.

### DETAILED DESCRIPTION

Hereinafter, aspects of the disclosure are described in detail with reference to the accompanying drawings. In assigning reference numerals to components of each drawing, the same components may be assigned the same numerals even when they are shown on different drawings. When determined to make the subject matter of the disclosure unclear, the detailed of the known art or functions may be skipped. As used herein, when a component “includes,” “has,” or “is composed of” another component, the component may add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” may be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components may be directly “connected”, “coupled” or “linked””, or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various aspects of the disclosure are described in detail with reference to the accompanying drawings.

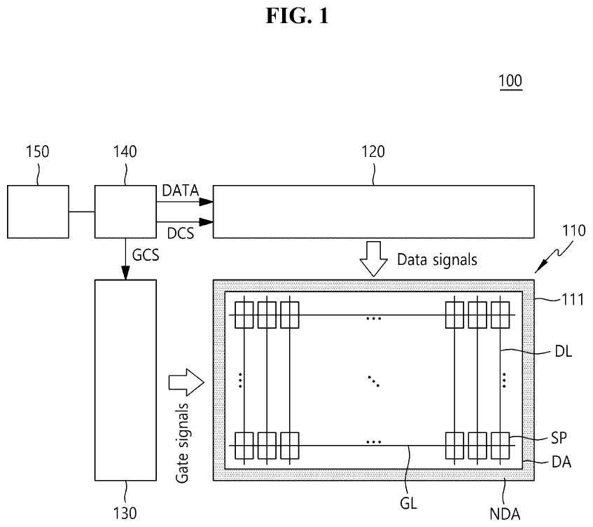

FIG. 1 is a system configuration diagram of a display device 100 according to aspects of the present disclosure.

Referring to FIG. 1, a display device 100 according to aspects of the present disclosure may include a display panel 110 and a display driving circuit as components for displaying an image. The display driving circuit is a circuit for driving the display panel 110, and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA located outside the display area DA.

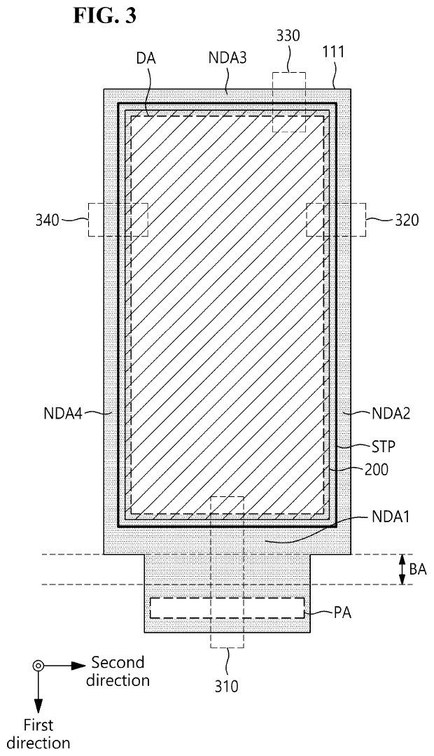

A plurality of subpixels SP for image display may be disposed in the display area DA, and the non-display area NDA may include a pad area PA (see FIG. 3) located in the first direction from the display area DA.

In a display panel 110 according to aspects of the present disclosure, the non-display area NDA may be very small. In this specification, the non-display area NDA may be also referred to as a “bezel.”

For example, the non-display area NDA may include a first non-display area located outside the display area DA in a first direction, a second non-display area located outside the display area DA in a second direction intersecting the first direction, a third non-display area located outside the display area DA in the opposite direction to the first direction, and a fourth non-display area located outside the display area DA in the direction opposite to the second direction. One or both of the first to fourth non-display areas may include a pad area to which the data driving circuit 120 is connected or bonded. Among the first to fourth non-display areas, two or three which do not include the pad area may be very small in size.

For another example, a boundary area between the display area DA and the non-display area NDA may be bent so that the non-display area NDA may be located below the display area. In this case, when the user looks at the display device 100 from the front, there may be little or no non-display area NDA visible to the user.

Various types of signal lines for driving a plurality of subpixels SP may be disposed on the substrate 111 of the display panel 110.

The display device 100 according to aspects of the present disclosure may be a liquid crystal display device or the like, or may be a self-luminous display device in which the display panel 110 emits light by itself. When the display device 100 according to aspects of the present disclosure is a self-luminous display device, each of the plurality of subpixels SP may include a light emitting device.

For example, the display device 100 according to aspects of the present disclosure may be an organic light emitting display device in which a light emitting device is implemented as an organic light emitting diode (OLED). For another example, the display device 100 according to aspects of the present disclosure may be an inorganic light emitting display device in which the light emitting device is implemented as an inorganic-based light emitting diode. For another example, the display device 100 according to aspects of the present disclosure may be a quantum dot display device in which a light emitting device is implemented with quantum dots, which are semiconductor crystals emitting light by itself.

The structure of each of the plurality of subpixels SP may vary depending on the type of the display device 100. For example, if the display device 100 is a self-luminous display device with the subpixel SP emitting light by itself, each subpixel SP may include a self-luminous light emitting device, one or more transistors, and one or more capacitors.

For example, various types of signal lines may include a plurality of data lines DL supplying data signals (also called data voltages or image signals) and a plurality of gate lines GL for transmitting gate signals (also called scan signals).

For example, the plurality of data lines DL and the plurality of gate lines GL may cross each other. Each of the plurality of data lines DL may be arranged to extend in a first direction. Each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will be exemplified a case in which each of the plurality of data lines DL is arranged in a column direction, and each of the plurality of gate lines GL is arranged in a row direction.

The data driving circuit 120 is a circuit for driving a plurality of data lines DL, and may output data signals to the plurality of data lines DL.

The data driving circuit 120 may receive image data DATA in digital form from the display controller 140 and convert the received image data DATA into analog data signals to output to a plurality of data lines DL.

For example, the data driving circuits 120 may be connected to the display panel 110 using a tape automated bonding (TAB) method, or may be connected to the bonding pad of the display panel 110 using a chip-on-glass (COG) or chip-on-panel (COP) method, or may be implemented using a chip-on-film (COF) method and connected to the display panel 110.

The data driving circuit 120 may be connected to one side (e.g., the upper or lower side) of the display panel 110. Depending on the driving method, panel design method, etc., the data driving circuit 120 may be connected to both sides (e.g., upper and lower sides) of the display panel 110, or may be connected to two or more of the four sides of the display panel 110.

The data driving circuit 120 may be connected to the outside of the display area DA of the display panel 110, but alternatively, it may be disposed in the display area DA of the display panel 110.

The gate driving circuit 130 is a circuit for driving a plurality of gate lines GL, and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, and may generate gate signals and supply the generated gate signals to the plurality of gate lines GL.

In the display device 100 according to aspects of the present disclosure, the gate driving circuit 130 may be built into the display panel 110 as a gate-in-panel (GIP) type. If the gate driving circuit 130 is a gate-in-panel type, the gate driving circuit 130 may be formed on a substrate of the display panel 110 during the manufacturing process of the display panel 110.

In the display device 100 according to aspects of the present disclosure, the gate driving circuit 130 may be disposed in the display area DA of the display panel 110. For example, the gate driving circuit 130 may be disposed in a first partial area within the display area DA (e.g., a left area or a right area within the display area DA). For another example, the gate driving circuit 130 may be disposed in a first partial area within the display area DA (e.g., a left area or a right area within the display area DA) and a second partial area within the display area DA (e.g., a right area or a left area within the display area DA).

In the present disclosure, a gate driving circuit 130 built into the display panel 110 as a gate-in-panel type may be referred to as a “gate-in-panel circuit.”

As described above, the gate driving circuit 130 of the gate-in-panel type may not be connected to or disposed in the non-display area NDA of the display panel 110, but may be disposed in the display area DA, thereby significantly reducing the bezel of the display panel 110.

The display controller 140 may be a device for controlling the data driving circuit 120 and the gate driving circuit 130, and may control the driving timing for the plurality of data lines DL and the driving timing of the plurality of gate lines GL.

The display controller 140 may supply a data driving control signal DCS to the data driving circuit 120 to control the data driving circuit 120, and may supply a gate driving control signal GCS to the gate driving circuit 130 to control the gate driving circuit 130.

The display controller 140 may receive input image data from a host system 150 and supply image data DATA to the data driving circuit 120 based on the input image data.

The display controller 140 may be implemented as a separate component from the data driving circuit 120, or may be integrated with the data driving circuit 120 and implemented as an integrated circuit.

The display controller 140 may be a timing controller used in typical display technology, or may be a control device capable of further performing other control functions including a timing controller, or may be a control device different from the timing controller, or may be a control device other than a timing controller, or may be a circuit within the control device. The display controller 140 may be implemented with various circuits or electronic components, such as an integrated circuit (IC), a field programmable gate array (FPGA), an application specific integrated circuit (ASIC), or Processor.

The display controller 140 may be mounted on a printed circuit board, a flexible printed circuit, etc., and may be electrically connected to the data driving circuit 120 and the gate driving circuit 130 through a printed circuit board, a flexible printed circuit.

The display controller 140 may transmit and receive signals with the data driving circuit 120 according to one or more predetermined interfaces. For example, the interface may include a low voltage differential signaling (LVDS) interface, an embedded clock point-point interface (EPI), or a serial peripheral interface (SPI).

To provide not only an image display function but also a touch sensing function, the display device 100 according to aspects of the present disclosure may include a touch sensor and a touch sensing circuit for detecting an occurrence of a touch by a touch object such as a finger or pen or detection a touch position by sensing the touch sensor.

The touch sensing circuit may include a touch driving circuit for driving and sensing a touch sensor to generate and output touch sensing data, and a touch controller for detecting the occurrence of a touch or detecting the touch position using touch sensing data.

The touch sensor may include a plurality of touch electrodes. The touch sensor may further include a plurality of touch lines to electrically connect a plurality of touch electrodes and the touch driving circuit.

The touch sensor may exist outside the display panel 110 in the form of a touch panel or may exist inside the display panel 110. If the touch sensor exists outside the display panel 110 in the form of a touch panel, the touch sensor may be referred to as an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor exists inside the display panel 110, the touch sensor may be formed on the substrate 111 along with signal lines and electrodes related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

If the touch sensing circuit performs touch sensing using a self-capacitance sensing method, the touch sensing circuit may perform touch sensing based on the capacitance between each touch electrode and a touch object (e.g., finger, pen, etc.). According to the self-capacitance sensing method, each of the plurality of touch electrodes may serve as a driving touch electrode and a sensing touch electrode. The touch driving circuit may drive all or part of the plurality of touch electrodes and sense all or part of the plurality of touch electrodes.

If the touch sensing circuit performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and the touch controller included in the touch sensing circuit may be implemented as separate devices or as one device. Additionally, the touch driving circuit and the data driving circuit may be implemented as separate devices or as one device.

Meanwhile, a plurality of touch lines (or a plurality of touch routing lines) for electrically connecting a plurality of touch electrodes constituting the touch sensor and the touch driving circuit may be disposed across the display area DA and extend into the pad area (e.g., a pad area PA in FIG. 3) without bypassing the non-display area (e.g., a second, third and fourth non-display areas NDA2, NDA3 and NDA4 in FIG. 3) in the non-display area NDA where the pad area (e.g., a pad area PA in FIG. 3) does not exist.

Accordingly, there may significantly reduce the size of the non-display area (e.g., a second, third and fourth non-display areas NDA2, NDA3 and NDA4 in FIG. 3) where the pad area (e.g., a pad area PA in FIG. 3) does not exist, thereby significantly reducing the bezel size.

The display device 100 may further include a power supply circuit which supplies various types of power to the display driving circuit and/or the touch sensing circuit.

The display device 100 according to aspects of the present disclosure may be a mobile terminal such as a smart phone or tablet, or a monitor or television of various sizes, but is not limited thereto, and may be a display of various types and sizes capable of displaying information or images.

The display device 100 according to aspects of the present disclosure may further include an electronic device such as a camera (e.g., image sensor) and a detection sensor. For example, the detection sensor may be a sensor for detecting an object or a human body by receiving light such as infrared, ultrasonic, or ultraviolet rays.

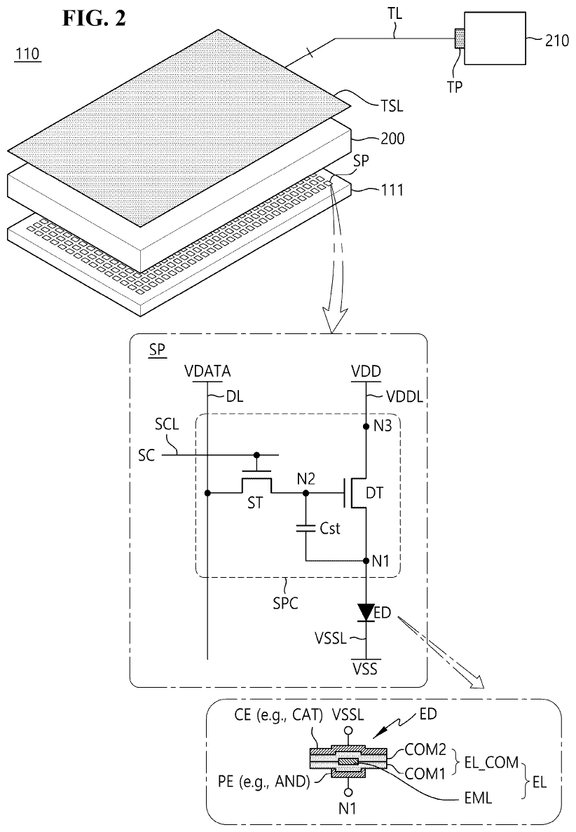

FIG. 2 illustrates a display panel 110 according to aspects of the present disclosure.

Referring to FIG. 2, the display panel 110 may include a substrate 111 on which a plurality of subpixels SP are disposed and an encapsulation layer 200 on the substrate 111. Here, the encapsulation layer 200 may also be referred to as an encapsulation substrate or an encapsulation portion.

Referring to FIG. 2, when the display device 100 according to aspects of the present disclosure is a self-luminous display device, each of the plurality of subpixels SP may include a light emitting device ED and a subpixel circuit SPC for driving the light emitting device ED.

Referring to FIG. 2, the subpixel circuit SPC may include a plurality of pixel driving transistors and at least one capacitor for driving the light emitting device ED. In the present disclosure, the subpixel circuit SPC may drive the light emitting device ED by supplying a driving current to the light emitting device ED at a predetermined timing. The light emitting device ED may be driven by a driving current and emit light.

The plurality of pixel driving transistors may include a driving transistor DT for driving the light emitting device ED, and a scan transistor ST which is turned on or off depending on the scan signal SC.

The driving transistor DT may supply driving current to the light emitting device ED.

The scan transistor ST may be configured to control the electrical state of a corresponding node in the subpixel circuit SPC or to control the state or operation of the driving transistor DT.

At least one capacitor may include a storage capacitor Cst to maintain a constant voltage during the frame.

To drive the subpixel SP, a data signal VDATA which is an image signal, and a scan signal SC which is a gate signal may be applied to the subpixel SP. In addition, a common pixel driving voltage including a first driving voltage VDD and a second driving voltage VSS may be applied to the subpixel SP to drive the subpixel SP.

The light emitting device ED may include a pixel electrode PE, an intermediate layer EL, and a common electrode CE. The intermediate layer EL may be located between the pixel electrode PE and the common electrode CE.

For example, the pixel electrode PE may be an anode AND, and the common electrode CE may be a cathode CAT. Alternatively, the pixel electrode PE may be a cathode CAT and the common electrode CE may be an anode AND. Hereinafter, for convenience of explanation, it will be exemplified a case where the pixel electrode PE is an anode AND and the common electrode CE is a cathode CAT.

In the case that the light emitting device ED is an organic light emitting device, the intermediate layer EL may include an emission layer EML, a first common intermediate layer COM1 between the anode AND and the emission layer EML, and a second common intermediate layer COM2 between the emission layer EML and the cathode. The emission layer EML may be disposed in each subpixel SP. In comparison, the first common intermediate layer COM1 and the second common intermediate layer COM2 may be commonly disposed across a plurality of subpixels SP. The emission layer EML may be disposed in each emission area, and the first common intermediate layer COM1 and the second common intermediate layer COM2 may be commonly disposed across a plurality of emission areas and non-emission areas. The first common intermediate layer COM1 and the second common intermediate layer COM2 may be collectively referred to as the common intermediate layer EL_COM.

For example, the first common intermediate layer COM1 may include a hole injection layer HIL and a hole transport layer HTL, and the second common intermediate layer COM2 may include an electron transport layer ETL and an electron injection layer EIL. The hole injection layer may inject holes from the anode AND to the hole transport layer, the hole transport layer may transport holes to the emission EML, the electron injection layer may inject electrons from the cathode CAT to the electron transport layer, and the electron transport layer may transport electrons to the emission layer EML.

For example, the cathode CAT may be electrically connected to a second driving voltage line VSSL. A second driving voltage VSS, which is a type of common pixel driving voltage, may be applied to the cathode CAT through the second driving voltage line VSSL. The anode AND may be electrically connected to a first node N1 of the driving transistor DT of each subpixel SP. In the present disclosure, the second driving voltage VSS may also be referred to as a base voltage VSS, and the second driving voltage line VSSL may also be referred to as a base voltage line VSSL.

For example, the pixel electrode PE may be an electrode disposed in each subpixel SP, and the common electrode CE may be an electrode commonly disposed in a plurality of subpixels SP.

Each light emitting device ED may be composed of overlapping parts of the pixel electrode PE, the intermediate layer EL and the common electrode CE. A predetermined emission area may be formed by each light emitting device ED. For example, the emission area of each light emitting device ED may include an area where the pixel electrode PE, the intermediate layer EL and the common electrode CE overlap.

For example, the light emitting device ED may be an organic light emitting diode (OLED), an inorganic light emitting diode, or a quantum dot light emitting device. For example, in the case that the light emitting device ED is an organic light emitting diode OLED, the intermediate layer EL in the light emitting device ED may include an organic intermediate layer EL containing an organic material.

The driving transistor DT may be a driving transistor for supplying driving current to the light emitting device ED. The driving transistor DT may be connected between a first driving voltage line VDDL and the light emitting device ED.

The driving transistor DT may include a first node N1 electrically connected to the light emitting device ED, a second node N2 to which the data signal VDATA is applied, and a third node N3 to which the driving voltage VDD is applied from the driving voltage line VDDL.

In the driving transistor DT, the second node N2 may be a gate node, the first node N1 may be a source node or a drain node, and the third node N3 may be a drain node or a source node. Hereinafter, for convenience of explanation, it will be described a case in which the second node N2 is a gate node, the first node N1 is a source node, and the third node N3 is a drain node in the driving transistor DT.

The scan transistor ST included in the subpixel circuit SPC illustrated in FIG. 2 may be a switching transistor for transmitting a data signal VDATA, which is an image signal, to the second node N2 which is the gate node of the driving transistor DT.

The scan transistor ST may be controlled on-off by the scan signal SC which is a gate signal applied through the scan line SCL as a type of gate line GL, and may control the electrical connection between the second node N2 of the driving transistor DT and the data line DL. The drain electrode or source electrode of the scan transistor ST may be electrically connected to the data line DL, and the source electrode or drain electrode of the scan transistor ST may be electrically connected to the second node N2 of the driving transistor DT. The gate electrode of the scan transistor ST may be electrically connected to the scan line SCL.

The storage capacitor Cst may be electrically connected between the first node N1 and the first node N2 of the driving transistor DT. The storage capacitor Cst may include a first capacitor electrode electrically connected to the first node N1 of the driving transistor DT or corresponding to the first node N1 of the driving transistor DT, and a second capacitor electrode electrically connected to the second node N2 of the driving transistor DT or corresponding to the second node N2 of the driving transistor DT.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DT.

Each of the driving transistor DT and the scan transistor ST may be an n-type transistor or a p-type transistor.

The display panel 110 may have a top emission structure or a bottom emission structure.

If the display panel 110 has a top emission structure, at least a portion of the subpixel circuit SPC may overlap with at least a portion of the light emitting device ED in the vertical direction. Alternatively, if the display panel 110 has a bottom emission structure, the subpixel circuit SPC may not overlap with the light emitting device ED in the vertical direction.

As shown in FIG. 2, the subpixel circuit SPC may have 2T-1C structure including two transistors DT and ST and one capacitor Cst. In some case, the subpixel circuit SPC may further include one or more transistors or one or more capacitors.

For example, the subpixel circuit SPC may have an 8T-1C structure including eight transistors and a single capacitor. For another example, the subpixel circuit SPC may have a 6T-2C structure including six transistors and two capacitors. For another example, the subpixel circuit SPC may have a 7T-1C structure including seven transistors and one capacitor.

Depending on the structure of the subpixel circuit SPC, there may vary the type and number of gate signal and/or gate lines supplied to the subpixel SP.

In addition, depending on the structure of the subpixel circuit SPC, there may vary the type and number of common pixel driving voltages supplied to the subpixel SP.

Since circuit elements within each subpixel SP (in particular, light emitting devices EDs implemented with organic light emitting diodes (OLEDs) containing organic materials) are vulnerable to external moisture or oxygen, an encapsulation layer 200 may be disposed on the display panel 110 to prevent oxygen from penetrating into the circuit elements (particularly, the light emitting device ED). The encapsulation layer 200 may be configured in various shapes to prevent the light emitting device ED from coming into contact with moisture or oxygen.

Referring to FIG. 2, to sense a touch of a user, the display device 100 according to aspects of the present disclosure may further include a touch sensor layer TSL including a plurality of sensor electrodes and a touch sensing circuit 210 configured to determine the presence or absence of touch or touch coordinates by sensing the plurality of sensor electrodes.

The touch sensor layer TSL may be built or embedded into the display panel 110. For example, the touch sensor layer TSL may be disposed on the encapsulation layer 200 within the display panel 110.

The display panel 110 may further include, in addition to the touch sensor layer TSL, a plurality of touch pads to which the touch sensing circuit 210 is electrically connected, and a plurality of touch routing lines TL for electrically connecting a plurality of sensor electrodes included in the touch sensor layer TSL and a plurality of touch pads to which the touch sensing circuit 210 is connected.

Meanwhile, the display device 100 according to an aspect of the present disclosure may have an extremely narrow bezel structure in which the non-display area NDA of the display panel 110 is very small or almost absent. Hereinafter, it will be described the extremely narrow bezel structure of the display panel 110 of the display device 100 according to an aspect of the present disclosure.

FIG. 3 illustrates a substrate 111 of a display panel 110 according to aspects of the present disclosure.

Referring to FIG. 3, the substrate 111 of the display panel 110 according to aspects of the present disclosure may include a display area DA in which an image is displayed and a non-display area NDA in which an image is not displayed.

Referring to FIG. 3, the non-display area NDA may include a first non-display area NDA1 located in a first direction from the display area DA, a second non-display area NDA2 located in a second direction from the display area DA, a third non-display area NDA3 located in a direction opposite to the first direction from the display area DA, and a fourth non-display area NDA4 located in a direction opposite to the second direction from the display area DA. For example, the first direction may be a column direction (e.g., Y-axis direction), and the second direction crossing the first direction may be a row direction (e.g., X-axis direction).

Referring to FIG. 3, the first non-display area NDA1 may include a pad area PA where a plurality of pads are disposed.

There may be disposed a plurality of pads to which the driving circuit is electrically connected in the pad area PA. A plurality of driving circuits or printed circuit boards may be electrically connected in the pad area. For example, the plurality of pads may include a plurality of display pads and a plurality of touch pads. A plurality of data lines, a first driving voltage line VDDL, and a second driving voltage line VSSL may be electrically connected to the plurality of display pads. A plurality of touch routing lines TL may be electrically connected to the plurality of touch pads.

Referring to FIG. 3, the first non-display area NDA1 may further include a bending area BA. In this case, the substrate 111 may be a flexible substrate. In some cases, the first non-display area NDA1 may not include the bending area BA.

Referring to FIG. 3, the display panel 110 may further include a ground line disposed in the non-display area NDA of the substrate 111. The ground line may be disposed from one point in the pad area PA to another point in the pad area PA via the second non-display area NDA2, the third non-display area NDA3, and the fourth non-display area NDA4.

Referring to FIG. 3, in the display panel 110 according to aspects of the present disclosure, the encapsulation layer 200 may have a structure in which an inorganic layer and an organic layer are stacked. In this case, an edge of the encapsulation layer 200 may be considered as an edge of the organic layer.

Referring to FIG. 3, the display panel 110 according to aspects of the present disclosure may include a stopper STP as a structure (i.e., an organic layer overflow prevention structure) to prevent overflow of the organic layer included in the encapsulation layer 200.

Referring to FIG. 3, in the display panel 110 according to aspects of the present disclosure, the stopper STP may be disposed in the non-display area NDA, and may be disposed in a ring shape surrounding the periphery of the organic layer.

Referring to FIG. 3, the stopper STP may be located between the display area DA and the pad area PA.

Referring to FIG. 3, in the display panel 110 according to aspects of the present disclosure, the stopper STP may be disposed in the non-display area NDA. In this way, even though the stopper STP is disposed in the non-display area NDA, there may not increase the size of the non-display area NDA due to the stopper STP.

In the display panel 110 according to aspects of the present disclosure, the stopper STP may serve to prevent overflow of the organic layer and reduce the non-display area NDA.

Hereinafter, it will be described in more detail the stopper STP, which is an organic layer overflow prevention structure capable of preventing overflow of the organic layer included in the encapsulation layer 200 and one of the extremely narrow bezel structures capable of significantly reducing the bezel size.

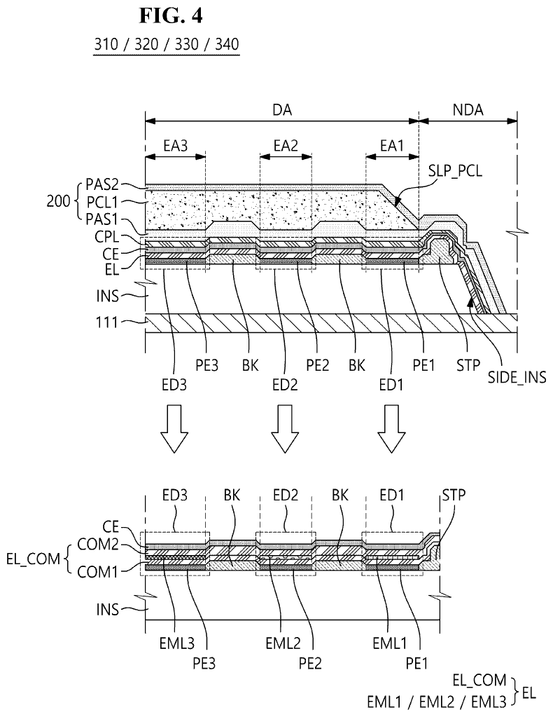

FIG. 4 is a cross-sectional view of a display panel 110 (corresponding to the part 310/320/330/340 in FIG. 3) according to aspects of the present disclosure.

Referring to FIG. 4, the display panel 110 according to aspects of the present disclosure may include a substrate 111, an insulating layer stack INS on the substrate 111, a plurality of light emitting devices ED1, ED2 and ED3 on the insulating layer stack INS, a first organic layer PCL1 on a plurality of light emitting devices ED1, ED2 and ED3, and a stopper STP disposed on the outside of the first organic layer PCL1.

The substrate 111 may include a display area DA and a non-display area NDA, and the non-display area NDA may include a second non-display area NDA2 located in a second direction from the display area DA.

The insulating layer stack INS may include a plurality of insulating layers located between the substrate 111 and the plurality of light emitting devices ED1, ED2 and ED3.

The insulating layer stack INS may be located on the substrate 111, and may have an outer side SIDE_INS in the non-display area NDA. The insulating layer stack INS may include a plurality of insulating layers.

The insulating layer stack INS may include a plurality of insulating layers required to form transistors. The insulating layer stack INS may include an organic insulating layer stack including at least one organic insulating layer, and an inorganic insulating layer stack including at least one inorganic insulating layer. For example, the organic insulating layer stack may include at least one planarization layer, the inorganic insulating layer stack may include at least one buffer layer, at least one gate insulating layer, or at least one interlayer insulating layer.

To form a plurality of light emitting devices ED1, ED2 and ED3 on the insulating layer stack INS, the display panel 110 may include a bank BK located on the insulating layer stack INS as a sub-pixel defining layer for dividing a plurality of emission areas EA1, EA2 and EA3 and having a plurality of openings, a plurality of pixel electrodes PE1, PE2 and PE3 located on the insulating layer stack INS and overlapping with a plurality of openings of the bank BK, a plurality of emission layers EML1, EML2 and EML3 located on a plurality of pixel electrodes PE1, PE2 and PE3, and a common electrode CE located on the plurality of emission layers EML1, EML2 and EML3 and extending from the display area DA to a portion of the non-display area NDA.

The plurality of pixel electrodes PE1, PE2 and PE3, a plurality of emission layers EML1, EML2 and EML3, and a common electrode CE may overlap to form a plurality of light emitting devices ED1, ED2 and ED3.

Referring to FIG. 4, the insulating layer stack INS may include a plurality of insulating layers disposed between the substrate 111 and a plurality of pixel electrodes PE1, PE2 and PE3.

Referring to FIG. 4, the display panel 110 according to aspects of the present disclosure may include a stopper STP which is not only an organic layer overflow prevention structure but also one of the extremely narrow bezel structures.

Referring to FIG. 4, the stopper STP may be located on the insulating layer stack INS, may be disposed in the non-display area NDA, and may be located further outside the first organic layer PCL1. The common electrode CE may be located on the insulating layer stack INS, and may extend from the display area DA to a portion of the non-display area NDA and overlap at least a portion of an upper surface of the stopper STP.

In the display panel 110 according to aspects of the present disclosure, the stopper STP may be disposed further outward than a first light emitting device ED1 which is the outermost light emitting device ED among the plurality of light emitting devices ED1, ED2 and ED3. The stopper STP may be disposed on the outer side of the first light emitting device ED1 which is the outermost light emitting device ED among the plurality of light emitting devices ED1, ED2 and ED3. The stopper STP may be disposed further outside the bank BK.

The stopper STP may include an organic material.

The stopper STP may have a thickness greater than the first pixel electrode PE1 of the first light emitting device ED1, which is the outermost light emitting device ED. For example, the stopper STP may have a thickness thicker than the sum of the thicknesses of the first pixel electrode PE1, the intermediate layer EL and the common electrode CE of the first light emitting device ED1 which is the outermost light emitting device ED. The intermediate layer EL of the first light emitting device ED1, which is the outermost light emitting device ED, may include a first common intermediate layer COM1, a first emission layer EML1, and a second common intermediate layer COM2.

For example, the highest upper surface of the stopper STP may be located higher than an upper surface of the common electrode CE in the emission areas EA1, EA2 and EA3. Accordingly, the common electrode CE may be disposed along the inner side of the stopper STP and extend upward to the upper portion of the stopper STP.

Referring F to FIG. 4, for example, the plurality of light emitting devices ED1, ED2 and ED3 may include a first light emitting device ED1 located in a first emission area EA1, a second light emitting device ED2 located in a second emission area EA2, and a third light emitting device ED3 located in a third emission area EA3.

The first light emitting device ED1 may include a first pixel electrode PE1, an intermediate layer EL, and a common electrode CE, and the intermediate layer EL of the first light emitting device ED1 may include a first common intermediate layer COM1, a first emission layer EML1 and a second common intermediate layer COM2.

The second light emitting device ED2 may include a second pixel electrode PE2, an intermediate layer EL, and a common electrode CE, and the intermediate layer EL of the second light emitting device ED2 may include a first common intermediate layer COM1, a second emission layer EML2 and a second common intermediate layer COM2.

The third light emitting device ED3 may include a third pixel electrode PE3, an intermediate layer EL, and a common electrode CE, and the intermediate layer EL of the third light emitting device ED3 may include a first common intermediate layer COM1, a third emission layer EML3 and a second common intermediate layer COM2.

The first pixel electrode PE1, the second pixel electrode PE2, and the third pixel electrode PE3 may be disposed in the first emission area EA1, the second emission area EA2, and the third emission area EA3, respectively.

The first emission layer EML1, the second emission layer EML2 and the third emission layer EML3 may be disposed in the first emission area EA1, the second emission area EA2, and the third emission area EA3, respectively.

The common intermediate layer EL_COM including the first common intermediate layer COM1 and the second common intermediate layer COM2, and the common electrode CE may be disposed throughout the display area DA, and may extend from the display area DA to at least a portion of the non-display area NDA.

Referring to FIG. 4, the display panel 110 according to aspects of the present disclosure may include a first inorganic layer PAS1, a first organic layer PCL1, and a second inorganic layer PAS2.

Referring to FIG. 4, the first inorganic layer PAS1 may be located on the common electrode CE, and may be disposed to extend from the display area DA to the non-display area NDA.

Referring to FIG. 4, the first organic layer PCL1 may be located on a portion of the first inorganic layer PAS1, and may have an outer inclined surface SLP_PCL.

Referring to FIG. 4, the second inorganic layer PAS2 may be located on the first organic layer PCL1, may be disposed to extend from the display area DA to the non-display area NDA, and may be disposed to extend along the outer inclined surface SLP_PCL of the first organic layer PCL1.

The first inorganic layer PAS1, the first organic layer PCL1, and the second inorganic layer PAS2 may be layers that constitute the encapsulation layer 200.

The stopper STP may be located on the insulating layer stack INS, and may be disposed further outside the first organic layer PCL1.

The first inorganic layer PAS1 may extend to the outer side SIDE_INS of the insulating layer stack INS along an upper portion and an outer side of the stopper STP.

The second inorganic layer PAS2 may extend to the outside of the outer inclined surface SLP_PCL of the first organic layer PCL1, and may be located on the first inorganic layer PAS1 extending to the outer side SIDE_INS of the insulating layer stack INS along the upper portion and the outer side of the stopper STP.

The bank BK may be located on the insulating layer stack INS, and may have first to third openings for defining or forming the first to third emission areas EA1, EA2 and EA3. The first to third openings may correspond to the first to third emission areas EA1, EA2 and EA3.

The first to third pixel electrodes PE1, PE2 and PE3 may be located on the insulating layer stack INS, and may overlap with the first to third openings of the bank BK, respectively.

The first common intermediate layer COM1 may be commonly disposed on the first to third pixel electrodes PE1, PE2 and PE3, and may also be disposed on the bank BK.

The first to third emission layers EML1, EML2 and EML3 may be located on the first common intermediate layer COM1, and may overlap with the first to third pixel electrodes PE1, PE2 and PE3. The first to third emission layers EML1, EML2 and EML3 may correspond to the first to third emission areas EA1, EA2 and EA3.

The second common intermediate layer COM2 may be commonly disposed on the first to third emission layers EML1, EML2 and EML3, and may also be disposed on the bank BK.

As described above, the common intermediate layer EL_COM including the first common intermediate layer COM1 and the second common intermediate layer COM2 may be disposed on the bank BK.

The common intermediate layer EL_COM may be disposed over the entire of the display area DA. Each of the first common intermediate layer COM1 and the second common intermediate layer COM2 may include an organic material.

The common electrode CE may be located on the second common intermediate layer COM2.

Referring to FIG. 4, the common intermediate layer EL_COM and the common electrode CE may extend to an upper portion of the stopper STP, and accordingly, the common intermediate layer EL_COM and the common electrode CE may overlap with at least part of the stopper STP.

For example, the common intermediate layer EL_COM and the common electrode CE may extend to the top and outer sides of the stopper STP. When the common intermediate layer EL_COM and the common electrode CE extend further, the common intermediate layer EL_COM and the common electrode CE may pass through the top and outer sides of the stopper STP and extend to the outer sides SIDE_INS of the insulating layer stack INS.

Referring to FIG. 4, the display panel 110 may further include a capping layer CPL located between the common electrode CE and the first inorganic layer PAS1 and extending from the display area DA to the non-display area NDA. The capping layer CPL may extend to the outer side SIDE_INS of the insulating layer stack INS along the upper portion and outer sides of the stopper STP.

Referring to FIG. 4, a common intermediate layer EL_COM, a common electrode CE and a capping layer CPL may be disposed on the outer side SIDE_INS of the insulating layer stack INS.

As described above, the stopper STP may be disposed on the outer side of the first light emitting device ED1, which is the outermost light emitting device ED among the plurality of light emitting devices ED1, ED2 and ED3 corresponding to the plurality of subpixels SP, and may have a thickness greater than that of the first pixel electrode PE1 of the first light emitting device ED1.

Referring to FIG. 4, a lower surface of the stopper STP may have a larger area than an upper surface of the stopper STP. The stopper STP may include a lower stopper part on the insulating layer stack INS, and an upper stopper part on the lower stopper part. The lower stopper part may include the same material (i.e., bank material) as the bank BK, and the upper stopper part may include the same material (i.e., spacer material) as the spacer on the bank BK. The bank material and/or spacer material may be the same material or may be different materials. The bank material and/or spacer material may include organic materials.

Each of the first inorganic layer PAS1 and the second inorganic layer PAS2 may be formed of silicon nitride, aluminum nitride, zirconium nitride, titanium nitride, hafnium nitride, tantalum nitride, silicon oxide, aluminum oxide, or titanium oxide.

For example, the first organic layer PCL1 may be formed of acryl resin, epoxy resin, phenolic resin, or polyimide resin. The first organic layer PCL1 may be formed in liquid form by being applied through an inkjet process and then through a curing process.

According to the stopper structure illustrated in FIG. 4, an extremely narrow bezel of the display panel 110 may be possible.

In the display panel 110 with a stopper STP illustrated in FIG. 4, the intermediate layer EL, the common electrode CE and the capping layer CPL may pass through the upper and outer sides of the stopper STP, and may be disposed to extend to the outside of the first organic layer PCL1 of the encapsulation layer 200. Accordingly, the intermediate layer EL, common electrode CE and capping layer CPL may be more likely to be exposed to a vulnerable environment. Here, a vulnerable environment may mean an environment exposed to moisture or oxygen.

Accordingly, when the display panel 110 includes the stopper STP illustrated in FIG. 4, there may be difficulty in securing reliability. When the display panel 110 includes the stopper STP illustrated in FIG. 4, there may not be easy to process to disconnect the intermediate layer EL, common electrode CE and capping layer CPL at the outermost point or inner point of the first organic layer PCL1 of the encapsulation layer 200.

Accordingly, the display device 100 according to aspects of the present disclosure may further provide a stopper structure that is advantageous for ensuring high reliability while enabling an extremely narrow bezel. Hereinafter, it will be described a stopper structure that is advantageous for ensuring high reliability while enabling an extremely narrow bezel with reference to the drawings.

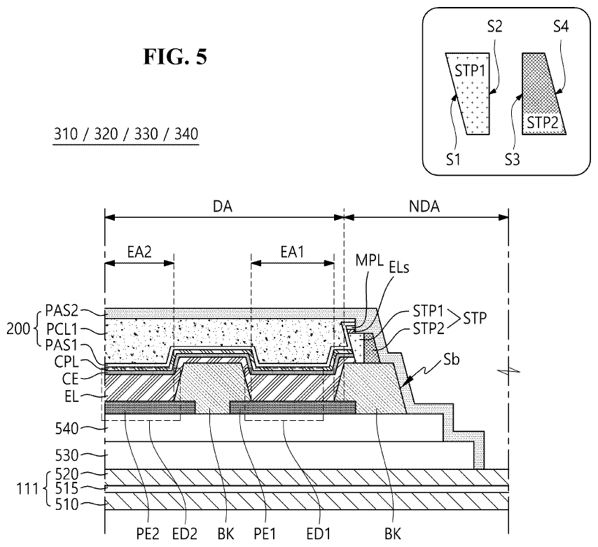

FIG. 5 is a cross-sectional view of a display panel 110 according to aspects of the present disclosure.

Referring to FIG. 5, the display device 100 according to aspects of the present disclosure may include a substrate 111 with a display area DA capable of displaying an image and a non-display area NDA different from the display area DA, a plurality of light emitting devices ED1 and ED2 disposed on the substrate 111, and a first organic layer PCL1 disposed on the plurality of light emitting devices ED1 and ED2.

Referring to FIG. 5, the display device 100 according to aspects of the present disclosure may include a stopper STP disposed outside the outermost light emitting device ED1 among the plurality of light emitting devices ED1 and ED2 and located outside the first organic layer PCL1.

Referring to FIG. 5, in the display device 100 according to aspects of the present disclosure, the stopper STP may be located higher than the pixel electrodes PE1 and PE2 of each of the plurality of light emitting devices ED1 and ED2. That is, the stopper STP may be further away from the substrate 111 than the pixel electrodes PE1 and PE2 of each of the plurality of light emitting devices ED1 and ED2.

Referring to FIG. 5, in the display device 100 according to aspects of the present disclosure, an inner side S1 of the stopper STP may have a reverse taper shape.

Referring to FIG. 5, in the display device 100 according to aspects of the present disclosure, an outer side S4 of the stopper STP may have a regular taper shape.

Referring to FIG. 5, the display device 100 according to aspects of the present disclosure may further include an intermediate layer EL which constitutes a plurality of light emitting device ED1 and ED2, and exists on the inner side S1 of the stopper STP, but does not exist on the outer side S4 of the stopper STP.

Referring to FIG. 5, the display device 100 according to aspects of the present disclosure may further include a separation material layers ELs disposed on an upper portion of the stopper STP, separated from the intermediate layer EL present on the inner side S1 of the stopper STP, and containing the same material as the intermediate layer EL.

Hereinafter, the display device 100 according to the aspects of the present disclosure will be described in more detail.

Referring to FIG. 5, the display device 100 according to aspects of the present disclosure may include a substrate 111 including a display area DA and a non-display area NDA, a plurality of light emitting devices ED1 and ED2 disposed on the substrate 111, a bank BK for defining the emission areas EA1 and EA2 of each of the plurality of light emitting devices ED1 and ED2, and an encapsulation layer 200 on the plurality of light emitting devices ED1 and ED2 and the bank BK.

The encapsulation layer 200 may include a first inorganic layer PAS1 on the plurality of light emitting devices ED1 and ED2 and the bank BK, a first organic layer PCL1 on the first inorganic layer PAS1, and a second inorganic layer PAS2 on the first organic layer PCL1.

Referring to FIG. 5, the display device 100 according to aspects of the present disclosure may further include a first insulating layer 530 disposed on a substrate 111 and a second insulating layer 540 on the first insulating layer 530.

At least one of the first insulating layer 530 and the second insulating layer 540 may include a planarization layer.

Referring to FIG. 5, a plurality of light emitting devices ED1 and ED2 may be disposed on the second insulating layer 540.

Referring to FIG. 5, the display device 100 according to aspects of the present disclosure may include a stopper STP disposed the outside of the display area DA and located on the outermost upper portion of the bank BK.

With respect to the horizontal position of the stopper STP, the stopper STP may be disposed on the outside of the display area DA, and at least a part of the stopper STP may be disposed further outside the first organic layer PCL1.

With respect to the vertical position of the stopper STP, the stopper STP may be located at the outermost upper part of the bank BK.

Regarding the shape of the stopper STP, the inner side S1 of the stopper STP may have a reverse taper shape. Additionally, the outer side S4 of the stopper STP may have a regular taper shape.

The inner side S1 of the stopper STP has a reverse taper shape, so that the intermediate layer EL, the common electrode CE and the capping layer CPL may not extend to the outside of the first organic layer PCL1, and may be disconnected near/at the outermost point of the first organic layer PCL1. As a result, there may be possible to secure high reliability of the display panel 110.

Since the outer side S4 of the stopper STP has a regular taper shape, the second inorganic layer PAS2 may not be disconnected at the outer side S4 of the stopper STP, and may cover the outer side of the bank BK and extend to or near the upper surface of the substrate 111 while completely covering the stopper STP. Accordingly, there may be improved the encapsulation performance of the encapsulation layer.

Regarding the material of the stopper STP, for example, the stopper STP may include an inorganic material. As another example, the stopper STP may include an organic material. As another example, the stopper STP may include inorganic and organic materials.

In the case that the stopper STP includes an inorganic material, there may be easy to form the inner side S1 of the stopper STP into a reverse tapered shape.

In the case that the stopper STP includes both inorganic and organic materials, there may be easy to form the inner side S1 of the stopper STP into a reverse taper shape, and the outer side S4 of the stopper STP into a regular taper shape.

Referring to FIG. 5, in the display device 100 according to aspects of the present disclosure, the stopper STP may include a first stopper part STP1 including a first side S1 and a second side S2, and a second stopper part STP2 including a third side S3 and a fourth side S4.

Referring to FIG. 5, the first stopper part STP1 may be located closer to the display area DA than the second stopper part STP2.

The first side S1 of the first stopper part STP1 may be located closer to the display area DA than the second side S2 of the first stopper part STP1.

The third side S3 of the second stopper part STP2 may be located closer to the display area DA than the fourth side S4 of the second stopper part STP2.

The second side S2 of the first stopper part STP1 and the third side S3 of the second stopper part STP2 may contact each other.

The first stopper part STP1 and the second stopper part STP2 included in the stopper STP may be integrated. Alternatively, the first stopper part STP1 and the second stopper part STP2 may be separately formed patterns.

The first stopper part STP1 and the second stopper part STP2 may be patterns formed simultaneously or may be patterns formed separately through different processes.

Referring to FIG. 5, in the display device 100 according to aspects of the present disclosure, the first side S1 of the first stopper part STP1 may be an inner side of the stopper STP, and may have a reverse taper shape.

Referring to FIG. 5, in the display device 100 according to aspects of the present disclosure, the fourth side surface S4 of the second stopper part STP2 may have a regular taper shape.

Since the first side S1 of the first stopper part STP1 has a reverse taper shape, the intermediate layer EL, the common electrode CE and the capping layer CPL may not extend to the outer edge of the first organic layer PCL1 and may be disconnected or broken near or at the outermost point of the first organic layer PCL1. As a result, there may be possible to secure high reliability of the display panel 110.

Since the fourth side S4 of the second stopper part STP2 has a regular taper shape, the second inorganic layer PAS2 may not be disconnected at the fourth side S4 of the second stopper part STP2, and may cover the outer side of the bank BK and extend to or near the upper surface of the substrate 111 while completely covering the stopper STP. Accordingly, there may be improved the encapsulation performance of the encapsulation layer.

Referring to FIG. 5, in the display device 100 according to aspects of the present disclosure, the first stopper part STP1 may include an inorganic material. When the first stopper part STP1 includes an inorganic material, there may be easy to form the first side S1 of the first stopper part STP1 into a reverse tapered shape.

Referring to FIG. 5, in the display device 100 according to aspects of the present disclosure, the second stopper part STP2 may include an inorganic material. If the second stopper part STP2 includes an inorganic material, there may be easy to form the first stopper part STP1 and the second stopper part STP2 simultaneously and integrally.

Referring to FIG. 5, in the display device 100 according to aspects of the present disclosure, the second stopper part STP2 may include an organic material.

If the second stopper part STP2 includes an organic material, there may be easy to form the fourth side S4 of the second stopper part STP2 into a regular taper shape. As a result, the second inorganic layer PAS2 may extend without being disconnected at the fourth side S4 of the second stopper part STP2. Accordingly, there may be improved the encapsulation performance of the encapsulation layer.

Referring to FIG. 5, each of the plurality of light emitting devices ED1 and ED2 may include a pixel electrode PE1 and PE2, an intermediate layer EL, and a common electrode CE.

Referring to FIG. 5, each of the plurality of light emitting devices ED1 and ED2 may include an emission layer EML and a common intermediate layer EL_COM. (see FIG. 2)

Referring to FIG. 5, the common intermediate layer EL_COM included in each intermediate layer EL of the plurality of light emitting devices ED1 and ED2 may be connected to each other, and the common intermediate layer EL_COM may be located on an inner side of the first side S1 of the first stopper part STP1.

Referring to FIG. 5, the display device 100 according to aspects of the present disclosure may further include a separation material layers ELs disposed on the stopper STP and containing the same material as the common intermediate layer EL_COM, but separated from the common intermediate layer EL_COM.

For example, the separation material layer ELs may be disposed on the first stopper part STP1 but not on the second stopper part STP2.

Referring to FIG. 5, the display device 100 according to aspects of the present disclosure may further include a metal patterning layer MPL disposed on the separation material layer ELs.

The metal patterning layer MPL may be disposed on the first stopper part STP1 but not on the second stopper part STP2.

The metal patterning layer MPL may be a layer for patterning the common electrode CE. For example, the metal patterning layer MPL may include an organic material.

Referring to FIG. 5, the display device 100 according to aspects of the present disclosure may further include a capping layer CPL disposed on the common electrode CE.

Referring to FIG. 5, in the display device 100 according to aspects of the present disclosure, the first inorganic layer PAS1 may extend from the display area DA to the non-display area NDA.

Referring to FIG. 5, in the display device 100 according to aspects of the present disclosure, the first inorganic layer PAS1 may be disposed on the separation material layer ELs by extending along the first side S1 of the first stopper part STP1 to the upper portion of the first stopper part STP1.

However, the first inorganic layer PAS1 may not be disposed on the fourth side S4 of the second stopper part STP2.

The first inorganic layer PAS1 may not be disposed on the second stopper part STP2.

Referring to FIG. 5, in the display device 100 according to aspects of the present disclosure, the first organic layer PCL1 may extend from the display area DA to the non-display area NDA.

Referring to FIG. 5, in the display device 100 according to aspects of the present disclosure, the first organic layer PCL1 may extend to an upper portion of the first stopper part STP1.

However, the first organic layer PCL1 may not be disposed on the fourth side S4 of the second stopper part STP2.

The first organic layer PCL1 may not be disposed on the second stopper part STP2.

Referring to FIG. 5, in the display device 100 according to aspects of the present disclosure, the second inorganic layer PAS2 may extend from the display area DA to the non-display area NDA.

Referring to FIG. 5, in the display device 100 according to aspects of the present disclosure, the second inorganic layer PAS2 may extend along the outer side S4 of the stopper STP and an outer side Sb of the bank BK.

Referring to FIG. 5, in the display device 100 according to aspects of the present disclosure, the substrate 111 may include a first substrate 510, a second substrate 520 disposed on the first substrate 510, and a substrate intermediate layer 515 between the first substrate 510 and the second substrate 520.

Each of the first substrate 510 and the second substrate 520 may be a polyimide (PI) layer. The substrate intermediate layer 515 may be an inorganic insulating layer. When a charge is charged to the first substrate 510, which is a polyimide layer, the substrate intermediate layer 515 may prevent charges from affecting transistors disposed on the second substrate 520 through the second substrate 520 which is a polyimide layer.

In addition, the substrate intermediate layer 515 may block moisture components from penetrating upward through the first substrate 510, which is a polyimide layer. For example, the substrate intermediate layer 515 may be formed of a single layer of silicon nitride (SiNₓ) or silicon oxide (SiOₓ) or a multilayer thereof, or may be formed of a double layer of silicon dioxide (SiO₂) and silicon nitride (SiNₓ), but is not limited thereto.

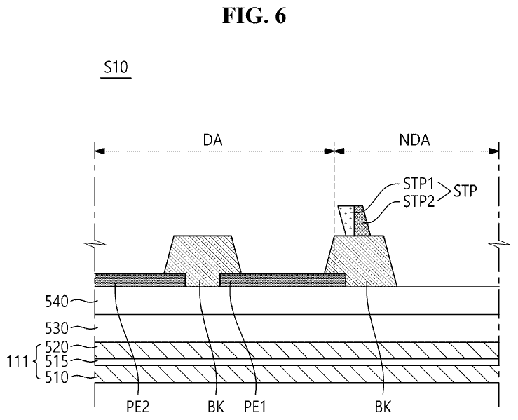

FIGS. 6 to 11 illustrate a manufacturing process of a display panel 110 according to aspects of the present disclosure.

Referring to FIG. 6, in step S10, a first insulating layer 530 may be disposed on the substrate 111, and a second insulating layer 540 may be disposed on the first insulating layer 530.

The substrate 111 may include a first substrate 510, a substrate intermediate layer 515, and a second substrate 520.

In step S10, a first pixel electrode PE1 and a second pixel electrode PE2 may be disposed on the second insulating layer 540.

In step S10, a bank BK may be disposed on the first pixel electrode PE1 and the second pixel electrode PE2, and may include the openings exposing a portion of the first pixel electrode PE1 and a portion of the second pixel electrode PE2.

In step S10, a stopper STP may be disposed on the outermost upper part of the bank BK.

The stopper STP may have an eaves structure. For this purpose, an inner side of the stopper STP may have a reverse taper shape.

An outer side of the stopper STP may have a regular taper shape.

For example, the stopper STP may include a first stopper part STP1 and a second stopper part STP2. The first stopper part STP1 may be located closer to the display area DA than the second stopper part STP2.

The outer side of the first stopper part STP1 and the inner side of the second stopper part STP2 may contact each other.

The first stopper part STP1 may have an eaves structure. An inner side of the first stopper part STP1 may have a reverse taper shape.

An outer side of the second stopper part STP2 may have a regular taper shape.

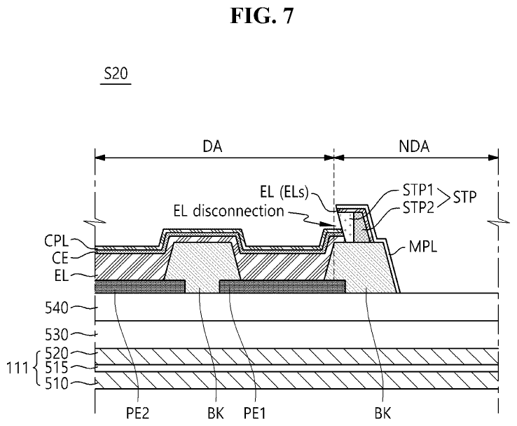

Referring to FIG. 7, in step S20, an intermediate layer EL may be disposed on the first pixel electrode PE1, the second pixel electrode PE2, and the bank BK.

In this case, in the intermediate layer EL, a portion disposed in the display area DA and a portion disposed on the stopper STP may be disconnected by the stopper STP.

In this specification, the portion of the intermediate layer EL disposed in the display area DA may be referred to as the intermediate layer EL, and the portion of the intermediate layer EL disposed on the stopper STP may be referred to as the separation material layer ELs.

Referring to FIG. 7, in step S20, a metal patterning layer MPL may be disposed on an upper portion the stopper STP, an outer side of the stopper STP, and an outer area of the stopper STP.

The metal patterning layer MPL may be a layer for patterning the common electrode CE. For example, the metal patterning layer MPL may include an organic material.

Referring to FIG. 7, in step S20, a common electrode CE may be disposed on the intermediate layer EL. In this case, the common electrode CE may be disposed only in areas where the metal patterning layer MPL is not disposed.

Accordingly, the common electrode CE may not be disposed on the upper portion of the stopper STP, the outer side of the stopper STP, and the outer area of the stopper STP.

Referring to FIG. 7, in step S20, a capping layer CPL may be disposed on the common electrode CE. The capping layer CPL may not be disposed on the top of the stopper STP, the outer side of the stopper STP, and the outer area of the stopper STP.

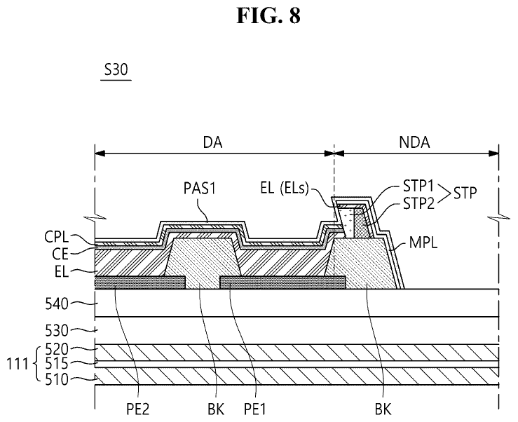

Referring to FIG. 8, in step S30, a first inorganic layer PAS1 may be disposed on the capping layer CPL. The first inorganic layer PAS1 may extend from an upper portion of the capping layer CPL to an upper portion of the stopper STP, the outer side of the stopper STP, and the outer area of the stopper STP.

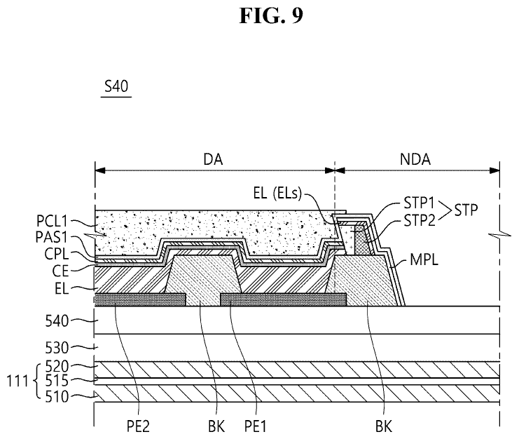

Referring to FIG. 9, in step S40, a first organic layer PCL1 may be disposed on the first inorganic layer PAS1. The first organic layer PCL1 may extend from the display area DA only to a portion of the top of the stopper STP.

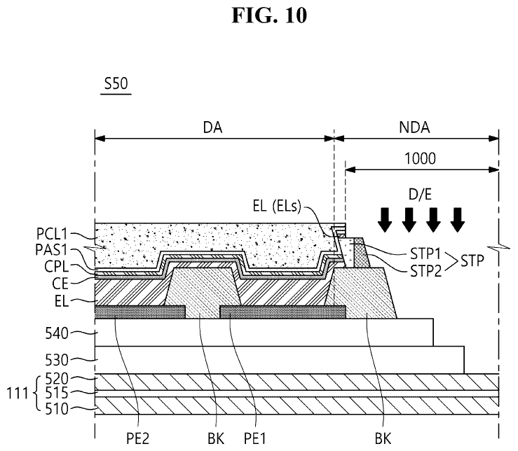

Referring to FIG. 10, in step S50, an etching process for the non-display area NDA may be performed. More specifically, an etching process may be performed in a predetermined etch area 1000.

Referring to FIG. 10, the etch area 1000 may be an area between an upper portion of the stopper STP and an outermost point of the substrate 111.

The innermost point of the etch area 1000 may be a portion of the upper portion of the stopper STP, for example, a point of the upper portion of the first stopper part STP1.

The etching process performed in step S50 may be a dry process (D/E).

By the etching process performed in step S50, there may be removed the separation material layer ELs, the metal patterning layer MPL and the first inorganic layer PAS1 from the etch area 1000. Accordingly, the reliability of the display panel 110 may be improved. For example, it is possible to reduce the possibility of moisture penetrating into the display area DA of the display panel 110.

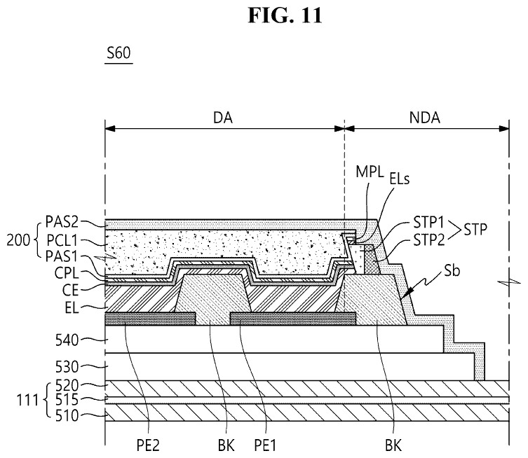

Referring to FIG. 11, in step S60, a second inorganic layer PAS2 may be disposed on the first organic layer PCL1 and the upper portion of the stopper STP, and may extend to the outer side of the stopper STP, and the outer area of the stopper STP.

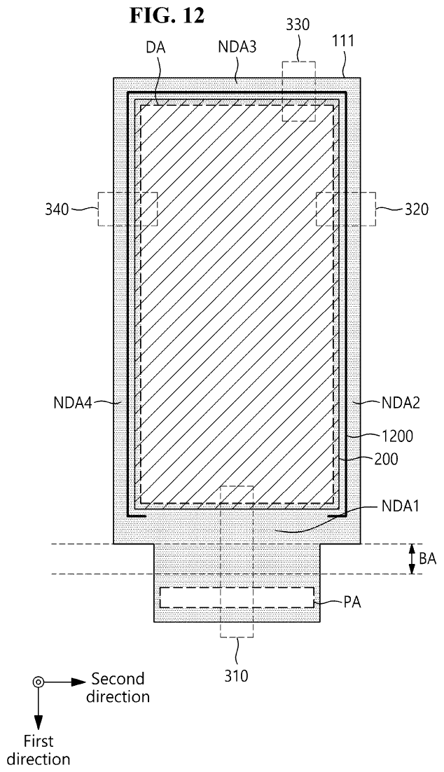

FIG. 12 illustrates a substrate 111 of a display panel 110 according to aspects of the present disclosure.

Referring to FIG. 12, the non-display area NDA may include a first non-display area NDA1 located outside the display area DA in the first direction and including a pad area, a second non-display area NDA2 located outside the display area DA in a second direction different from the first direction, a third non-display area NDA3 located outside the display area DA in a direction opposite to the first direction, and a fourth non-display area NDA4 located outside the display area DA in a direction opposite to the second direction.

Referring to FIG. 12, the substrate 111 may include a groove 1200 formed in the non-display area NDA.

Referring to FIG. 12, the groove 1200 may not be formed in at least part of the first non-display area NDA1, and may be formed in a second non-display area NDA2, a third non-display area NDA3 and a fourth non-display area NDA4.

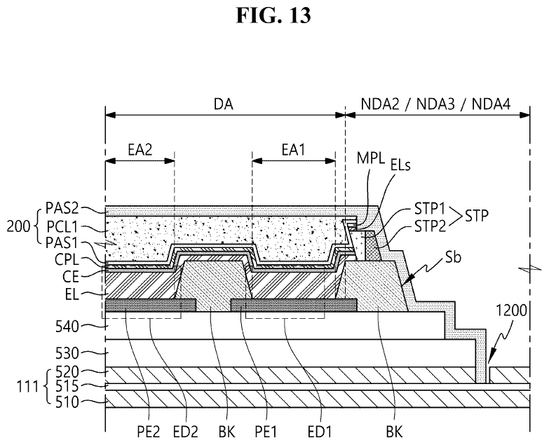

Referring to FIG. 12, the groove 1200 may be formed in a trench shape along the second non-display area NDA2, the third non-display area NDA3 and the fourth non-display area NDA4. The groove 1200 may be located further outside the stopper STP (see FIG. 13).

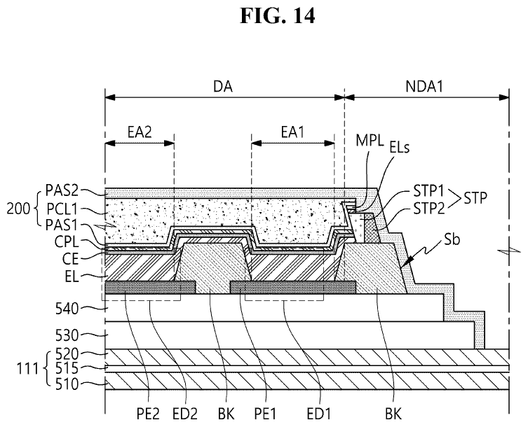

FIG. 13 is a cross-sectional view of second to fourth non-display areas NDA2, NDA3 and NDA4 of a display panel 110 according to aspects of the present disclosure, and FIG. 14 is a cross-sectional view of a first non-display area NDA1 of a display panel 110 according to aspects of the present disclosure.

Referring to FIG. 13, grooves 1200 are formed in the second non-display area NDA2, the third non-display area NDA3, and the fourth non-display area NDA4. The groove 1200 may be formed in a trench shape along the second non-display area NDA2, third non-display area NDA3, and fourth non-display area NDA4.

Referring to FIG. 13, the second inorganic layer PAS2 may extend from the display area DA to the non-display area NDA, and may extend to an inside of the groove 1200 along the side of the stopper STP and the side of the bank BK.

Referring to FIG. 13, the substrate 111 may include a first substrate 510, a second substrate 520 disposed on the first substrate 510, and a substrate intermediate layer 515 between the first substrate 510 and the second substrate 520. In this case, the groove 1200 may be formed in the second substrate 520.

Referring to FIG. 14, the groove 1200 may not be formed in at least part of the first non-display area NDA1.

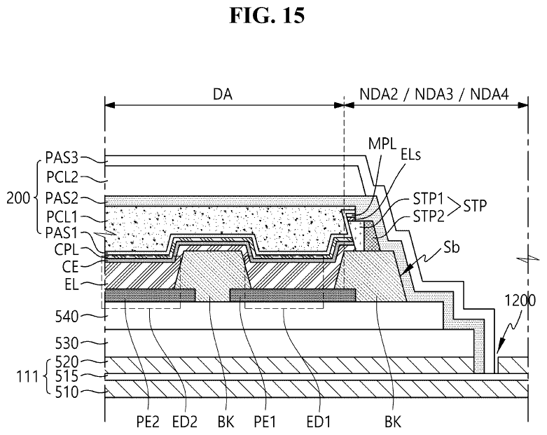

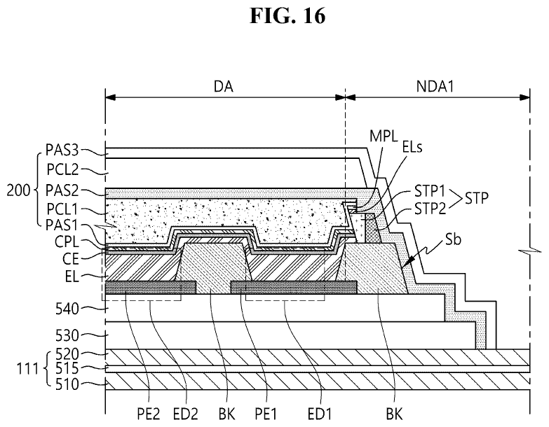

FIG. 15 is another cross-sectional view of second to fourth non-display areas NDA2, NDA3 and NDA4 of the display panel 110 according to aspects of the present disclosure, and FIG. 16 is another cross-sectional view of the first non-display area NDA1 of the display panel 110 according to aspects of the present disclosure.

Referring to FIGS. 15 and 16, the display panel 110 according to aspects of the present disclosure may further include a second organic layer PCL2 disposed on the second inorganic layer PAS2, and a third inorganic layer PAS3 disposed on the second organic layer PCL2.

Referring to FIGS. 15 and 16, the third inorganic layer PAS3 may extend along the side of the second organic layer PCL2, and may further extend onto/above the second inorganic layer PAS2 located outside the bank BK.

Referring to FIG. 15, the grooves 1200 may be formed in the second non-display area NDA2, the third non-display area NDA3, and the fourth non-display area NDA4. The groove 1200 may be formed in a trench shape along the second non-display area NDA2, third non-display area NDA3, and fourth non-display area NDA4.

Referring to FIG. 15, the second inorganic layer PAS2 and the third inorganic layer PAS3 may extend from the display area DA to the non-display area NDA, and may extend to an inside of the groove 1200 along the side of the stopper STP and the side of the bank BK.

Referring to FIG. 16, the groove 1200 may not be formed in at least part of the first non-display area NDA1.

Aspects of the present disclosure described above are briefly described as follows.

A display device according to aspects of the present disclosure may include a substrate including a display area capable of displaying an image and a non-display area different from the display area, a plurality of light emitting devices disposed on the substrate, a bank for defining an emission area of each of the plurality of light emitting devices, a first inorganic layer on the plurality of light emitting devices and the bank, a first organic layer on the first inorganic layer, a second inorganic layer on the first organic layer, and a stopper disposed outside the display area and located on the outermost upper part of the bank.

At least a portion of the stopper may be disposed further outside the first organic layer.

An inner side of the stopper may have a reverse taper shape.

An outer side of the stopper may have a regular taper shape.

The stopper may include an inorganic material.

An intermediate layer of each of the plurality of light emitting devices may include a common intermediate layer.

The common intermediate layers included in the intermediate layers of each of the plurality of light emitting devices may be connected to each other.

The common intermediate layer may be located inside the stopper.

The display device may further include a separation material layer disposed on the stopper, including the same material as the common intermediate layer, and separated from the common intermediate layer.

The separation material layer may be disposed on the stopper, and may not be disposed on an outside of the stopper.

The display device may further include a metal patterning layer disposed on the separation material layer.

The metal patterning layer may be disposed on the stopper, and may not be disposed on the outside of the stopper.

The first inorganic layer may extend along the inner side of the stopper to an upper portion of the stopper and may be disposed on the separation material layer.

The first inorganic layer may not be disposed on the outside of the stopper.

The first organic layer may extend to the upper portion of the stopper, and may not be disposed on the outside of the stopper.

The stopper may include a first stopper part including a first side and a second side, and a second stopper part including a third side and a fourth side.

The first stopper part may be located closer to the display area than the second stopper part.

The first side of the first stopper part may be located closer to the display area than the second side of the first stopper part.

The third side of the second stopper part may be located closer to the display area than the fourth side of the second stopper part.

The second side of the first stopper part and the third side of the second stopper part may be in contact with each other.

The first side of the first stopper part may have a reverse taper shape as the inner side of the stopper.

The fourth side of the second stopper part may have a regular taper shape.

The first stopper part may include an inorganic material.

The second stopper part may include an inorganic material or an organic material.

Each of the plurality of light emitting devices may include a pixel electrode, an intermediate layer, and a common electrode.

The intermediate layer of each of the plurality of light emitting devices may include a common intermediate layer.

The common intermediate layers included in the intermediate layers of each of the plurality of light emitting devices may be connected to each other.

The common intermediate layer may be located inside the stopper.

The display device according to aspects of the present disclosure may further include a separation material layer disposed on the stopper, including the same material as the common intermediate layer, and separated from the common intermediate layer.

The separation material layer may not be disposed on an outside of the stopper.

The separation material layer may be disposed on the first stopper part, but may not be disposed on the second stopper part.

The display device according to aspects of the present disclosure may further include a metal patterning layer disposed on the separation material layer.

The metal patterning layer may not be disposed on the outside of the stopper.

The metal patterning layer may be disposed on the first stopper part, but may not be disposed on the second stopper part.

The display device according to aspects of the present disclosure may further include a capping layer disposed on the common electrode.

The capping layer may not be disposed on the outer side of the stopper.

The first inorganic layer may extend along the inner side of the stopper to an upper portion of the stopper, and may be disposed on the separation material layer.

The first inorganic layer may not be disposed on the outer side of the stopper.

The first inorganic layer may extend along a first side of a first stopper part to an upper portion of the first stopper part, and may be disposed on the separation material layer.

The first inorganic layer may not be disposed on a fourth side of the second stopper part.

The first organic layer may extend to an upper portion of the stopper, and may not be disposed on the outer side of the stopper.

The first organic layer may extend to an upper portion of the first stopper part, and the first organic layer may not be disposed on a fourth side of the second stopper part.

The second inorganic layer may extend from the display area to the non-display area, and the second inorganic layer may extend along the outer side of the stopper and the outer side of the bank.

The display device according to aspects of the present disclosure may further include a second organic layer disposed on the second inorganic layer, and a third inorganic layer disposed on the second organic layer.

The third inorganic layer may extend along a side of the second organic layer, and may further extend to an upper portion of the second inorganic layer located outside the bank.

The non-display area may include a first non-display area located outside the display area in a first direction and including a pad area, a second non-display area located outside the display area in a second direction different from the first direction, a third non-display area located outside the display area in a direction opposite to the first direction, and a fourth non-display area located outside the display area in a direction opposite to the second direction.

The substrate may include a groove formed in the non-display area.

The groove may not be formed in at least a portion of the first non-display area, and may be formed in a trench shape along the second non-display area, the third non-display area, and the fourth non-display area,

The second inorganic layer may extend from the display area to the non-display area, and may extend to an inside of the groove along a side of the stopper and a side of the bank.

The substrate may include a first substrate, a second substrate disposed on the first substrate, and a substrate intermediate layer between the first substrate and the second substrate. The groove may be formed in the second substrate.

Each of the plurality of light emitting devices may comprise a pixel electrode, an intermediate layer, and a common electrode.

The stopper may be further away from the substrate than the pixel electrode of each of the plurality of light emitting devices.

The display device may further comprise a capping layer located between the common electrode and the first inorganic layer and extending from the display area to the non-display area.

The intermediate layer, the common electrode and the capping layer do not extend to the outside of the first organic layer, and are disconnected at the outermost point of the first organic layer.

The display device may further comprise a separation material layer which is disposed on the first stopper part but not on the second stopper part.

The display device may further comprise a metal patterning layer which is disposed on the separation material layer.

The metal patterning layer may be disposed on the first stopper part but not on the second stopper part.

The first inorganic layer may not be disposed on the second stopper part.

The first organic layer may not be disposed on the second stopper part.

The substrate intermediate layer may be an inorganic insulating layer.

In the intermediate layer, a portion disposed in the display area and a portion disposed on the stopper may be disconnected by the stopper.

The display device according to aspects of the present disclosure may include a substrate including a display area and a non-display area, a plurality of light emitting devices disposed on the substrate, a first organic layer disposed on the plurality of light emitting devices, and a stopper disposed further outward than the outermost light emitting device among the plurality of light-emitting devices, located outside the first organic layer, and having an inner side with a reverse taper shape.

The display device according to aspects of the present disclosure may further include an intermediate layer constituting the plurality of light emitting devices, present on the inner side of the stopper, and not present on an outer side of the stopper, and a separation material layer disposed on an upper portion of the stopper, separated from the intermediate layer, and including the same material as the intermediate layer.

An outer side of the stopper may have a regular taper shape.

The stopper may include a first stopper part including a first side and a second side, and a second stopper part including a third side and a fourth side.

The first stopper part may be located closer to the display area than the second stopper part, the first side of the first stopper part may be located closer to the display area than the second side of the first stopper part, and the third side of the second stopper part may be located closer to the display area than the fourth side of the second stopper part.

The second side of the first stopper part and the third side of the second stopper part may be in contact with each other, and the first side of the first stopper part may have a reverse taper shape as the inner side of the stopper.

The above description and the accompanying drawings provide an example of the technical idea of the present disclosure for illustrative purposes only. Various modifications, additions and substitutions to the described aspects will be readily apparent to those skilled in the art without departing from the spirit and scope of the present disclosure. In addition, the disclosed aspects are intended to illustrate the scope of the technical idea of the present disclosure. Thus, it is intended that the present disclosure covers the modifications and variations of the aspects provided they come within the scope of the appended claims and their equivalents.

What is claimed is:

1. A display device comprising:
a substrate including a display area capable of displaying an image and a non-display area different from the display area;
a plurality of light emitting devices disposed on the substrate;
a bank for defining an emission area of each of the plurality of light emitting devices;
a first inorganic layer on the plurality of light emitting devices and the bank;
a first organic layer on the first inorganic layer;
a second inorganic layer on the first organic layer; and
a stopper disposed outside the display area and located on the outermost upper part of the bank,
wherein at least a portion of the stopper is disposed further outside the first organic layer, and
wherein an inner side of the stopper has a reverse taper shape.

2. The display device of claim 1, wherein an outer side of the stopper has a regular taper shape.

3. The display device of claim 1, wherein the stopper includes an inorganic material.

4. The display device of claim 1, wherein the stopper includes a first stopper part including a first side and a second side, and a second stopper part including a third side and a fourth side,
wherein the first stopper part is located closer to the display area than the second stopper part, the first side of the first stopper part is located closer to the display area than the second side of the first stopper part, and the third side of the second stopper part is located closer to the display area than the fourth side of the second stopper part, and
wherein the second side of the first stopper part and the third side of the second stopper part are in contact with each other, and the first side of the first stopper part has a reverse taper shape as the inner side of the stopper.

5. The display device of claim 4, wherein the fourth side of the second stopper part has a regular taper shape.

6. The display device of claim 4, wherein the first stopper part includes an inorganic material.

7. The display device of claim 4, wherein the second stopper part includes an inorganic material.

8. The display device of claim 4, wherein the second stopper part includes an organic material.

9. The display device of claim 1, wherein each of the plurality of light emitting devices includes a pixel electrode, an intermediate layer, and a common electrode,
wherein the intermediate layer of each of the plurality of light emitting devices includes a common intermediate layer,
wherein the common intermediate layers included in the intermediate layers of each of the plurality of light emitting devices are connected to each other,
wherein the common intermediate layer is located inside the stopper, and
wherein the display device further comprises a separation material layer disposed on the stopper, including the same material as the common intermediate layer, and separated from the common intermediate layer.

10. The display device of claim 9, wherein the separation material layer is disposed on the stopper and is not disposed outside the stopper.

11. The display device of claim 10, further comprising a metal patterning layer disposed on the separation material layer,
wherein the metal patterning layer is disposed on the stopper and is not disposed on the outside of the stopper.

12. The display device of claim 9, wherein the first inorganic layer extends along the inner side of the stopper to an upper portion of the stopper and is disposed on the separation material layer, and
wherein the first inorganic layer is not disposed on the outside of the stopper.

13. The display device of claim 12, wherein the first organic layer extends to the upper portion of the stopper and is not disposed on the outside of the stopper.

14. The display device of claim 1, wherein the second inorganic layer extends from the display area to the non-display area, and
wherein the second inorganic layer extends along an outer side of the stopper and an outer side of the bank.

15. The display device of claim 1, further comprising:
a second organic layer disposed on the second inorganic layer; and
a third inorganic layer disposed on the second organic layer,
wherein the third inorganic layer extends along a side of the second organic layer and further extends above the second inorganic layer located outside the bank.

16. The display device of claim 1, wherein the non-display area includes:
a first non-display area located outside the display area in a first direction and including a pad area;
a second non-display area located outside the display area in a second direction different from the first direction;
a third non-display area located outside the display area in a direction opposite to the first direction; and
a fourth non-display area located outside the display area in a direction opposite to the second direction,
wherein the substrate includes a groove formed in the non-display area,
wherein the groove is not formed in at least a portion of the first non-display area, and is formed in a trench shape along the second non-display area, the third non-display area, and the fourth non-display area, and
wherein the second inorganic layer extends from the display area to the non-display area, and extends to an inside of the groove along a side of the stopper and a side of the bank.

17. The display device of claim 16, wherein the substrate includes:
a first substrate;
a second substrate disposed on the first substrate; and
a substrate intermediate layer between the first substrate and the second substrate, wherein the groove is formed in the second substrate.

18. A display device comprising:
a substrate including a display area and a non-display area;
a plurality of light emitting devices disposed on the substrate;
a first organic layer disposed on the plurality of light emitting devices; and
a stopper disposed further outward than the outermost light emitting device among the plurality of light-emitting devices, located outside the first organic layer, and having an inner side with a reverse taper shape.

19. The display device of claim 18, further comprising:
an intermediate layer constituting the plurality of light emitting devices, present on the inner side of the stopper, and not present on an outer side of the stopper; and
a separation material layer disposed on an upper portion of the stopper, separated from the intermediate layer, and including the same material as the intermediate layer.

20. The display device of claim 18, wherein an outer side portion of the stopper has a regular taper shape.
